(19) United States
(12) Patent Application Publication
(10) Pub. No.: US 2025/0132223 A1
(43) Pub. Date: Apr. 24, 2025

(54) DEVICES AND METHODS FOR FORMING DEVICES WITH LIDS

(71) Applicant: Taiwan Semiconductor Manufacturing Company, Ltd., Hsinchu (TW)

(72) Inventors: Yu-Shiou Tsai, Tainan (TW); Chang-Jung Hsueh, Taipei (TW); Chun-Lung Jao, Nantou (TW); Po-Yao Lin, Hsinchu (TW); Kathy Wei Yan, Hsinchu (TW)

(73) Assignee: Taiwan Semiconductor Manufacturing Company, Ltd., Hsinchu (TW)

(21) Appl. No.: 18/491,207

(22) Filed: Oct. 20, 2023

(51) Int. Cl. H01L 23/373; H01L 23/00; H01L 23/367; H01L 23/498

(52) U.S. Cl. CPC H01L 23/3736; H01L 23/3675; H01L 23/49822; H01L 24/08; H01L 24/16; H01L 2224/08146; H01L 2224/16227; H01L 2224/16235; H01L 2924/143; H01L 2924/1611; H01L 2924/182

(57) ABSTRACT

Provided are devices and methods for forming devices. A device includes a workpiece; a thermal interface material (TIM) disposed over the workpiece; and a lid disposed over the workpiece, wherein the lid has an underside formed with a trench, and wherein a vertically extending portion of the TIM extends into the trench and a base portion of the TIM is located outside of the trench.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. In some device, multiple dies are stacked vertically to reduce the footprint of a device package and permit dies with different processing technologies to be interconnected. As the sizes of active devices on a die shrink, the heat dissipation for the increasingly compact active devices is managed by attaching a lid over the stacked dies. The lid protects the dies and provides a path to conduct heat away from the dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an overhead schematic view of a workpiece locating over a carrier package during a stage of fabrication, in accordance with some embodiments.

FIG. 2 is an overhead schematic view of a lid positioned over the workpiece and carrier package of FIG. 1, in accordance with some embodiments.

FIG. 3 is a cross-sectional view taken along line 3-3 in FIGS. 1 and 2, in accordance with some embodiments.

FIG. 4 is a focused view of the trench in the lid of FIG. 3, in accordance with some embodiments.

FIG. 5 is a cross-sectional view taken along line 5-5 in FIGS. 1 and 2, in accordance with some embodiments.

FIG. 6 is a cross-sectional view taken along line 6-6 in FIGS. 1 and 2, in accordance with some embodiments.

FIG. 7 is a cross-sectional schematic similar to FIG. 3, illustrating the structure of the device before a thermal anneal process.

FIG. 8 is a cross-sectional schematic of the structure of FIG. 7 after a thermal anneal process.

FIG. 9 is a cross-sectional schematic similar to FIG. 6, illustrating the structure of the device before a thermal anneal process.

FIG. 10 is a cross-sectional schematic of the structure of FIG. 9 after a thermal anneal process.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. As used herein, “directly over” refers to a vertical alignment of features such that when an overlying feature that is directly over an underlying feature, a vertical axis passes through both features.

On the over hand, “above” refers to a relative height of two features, such that when an upper feature is above a lower feature, the upper feature is at a greater relative height than the lower feature. An upper feature above a lower feature may be or may not be directly over the lower feature. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “directly over”, “over”, “overlying”, “above”, “upper”, “top”, “under”, “underlying”, “beneath”, “below”, “lower”, “bottom”, “side”, “positive slope” and “negative slope” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

All numbers in this description indicating amounts, ratios of materials, physical properties of materials, and/or use are to be understood as modified by the word “about,” except as otherwise explicitly indicated. When modifying a numerical value in the specification or claims, “about” denotes an interval of accuracy, familiar and acceptable to a person skilled in the art. In general, such interval of accuracy is ±ten percent. Thus, “about ten” means nine to eleven.

Unless otherwise identified, in certain embodiments herein, a “material layer” is a layer that includes at least 50 wt. % of the identified material, for example at least 60 wt. % of the identified material, or at least 75 wt. % of the identified material, or at least 90 wt. % of the identified material; and a layer that is a “material” includes at least 50 wt. % of the identified material, for example at least 60 wt. % of the identified material, at least 75 wt. % of the identified material, at least 90 wt. % of the identified material, or at least 99 wt. % of the identified material. For example, certain embodiments, each of a titanium nitride layer and a layer that is titanium nitride is a layer that is at least 50 wt. %, at least 60 wt. %, at least 75 wt. %, titanium nitride, at least 90 wt. %, titanium nitride, or at least 99 wt. % titanium nitride.

For the sake of brevity, well-known techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Embodiments will be described with respect to a specific context, bonding lids, heat sinks covers, casing or the like to wafers, dies, substrates or other structures. Other embodiments may also be applied, however, to the bonding of substrates, packages, structures or devices or combinations of any type of integrated circuit device or component.

Cooling devices, packaged semiconductor devices, and methods of packaging semiconductor devices are disclosed in the present disclosure. The cooling devices are implementable in portable electronic equipment, such as cellular phones, smart phones, tablets, notebooks, and other applications. The cooling devices are implementable on packaged semiconductor devices that may comprise one substrate attached to another substrate, wherein each substrate may be a die, wafer, printed circuit board, packaging substrate, or the like. The cooling devices thereby allow for cooling of die-to-die, wafer-to-die, wafer-to-wafer, die or wafer to printed circuit board or packaging substrate types of packaging, or the like.

Embodiment herein may enhance TIM coverage and reduce TIM stress. Further, embodiments herein may provide a low stress trench and composite design for trench and dam to reduce metal TIM stress and enhance TIM coverage. Embodiments may be provided for use in High-Performance Computing (HPC) packages.

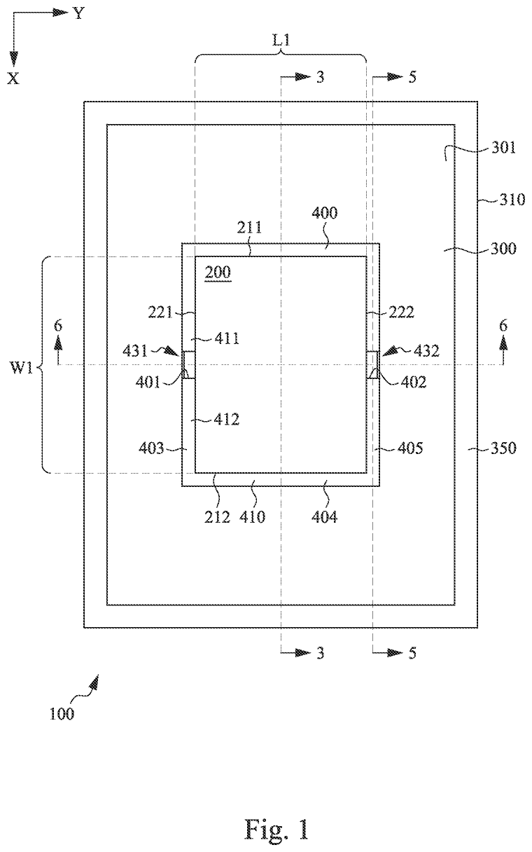

The embodiments of the present disclosure are described with reference to FIGS. 1 through 10, and variations of the embodiments are also discussed. Three dimensional integrated circuit (3D IC) packages are commonly formed by attaching one or more top dies to carrier dies, which are in turn attached to a package substrate. These dies and substrate are attached by way of, for example, ball grid arrays (BGAs), land grid arrays (LGAs), solder balls, studs, wire bonds, or other conductive connectors. One or more of the dies may be formed with a seal ring in a redistribution layer (RDL) around the outside edge of the die. The seal ring may be formed of metal elements extending through the dielectric layers of the RDL. The seal ring prevents the dielectric layers from peeling, particularly when the die is sawn from the wafer. In order to ensure that the stacked dies remain connected and the conductive connections between the dies remain intact an underfill may be applied between the dies. A lid acting as a heat sink may be applied over the dies with a thermal interface material (TIM) between the lid and the underlying components.

Described herein are embodiments in which processing of the TIM is improved. For example, a metal TIM may melt during thermal annealing. Herein, structures and features provide for directing flow of melted TIM portions to desired locations or in desired directions and limiting flow of melted TIM portions to undesired locations or in undesired directions. For example, embodiments herein may provide a trench in the underside of the lid. The trench provides an open space or region to receive flow of melted TIM portions in a vertical direction and to reduce stress on the TIM. In some embodiments, the lid is provided with downward-extending protrusions that surround the TIM in a longitudinal direction and block or inhibit flow of melted portions of the TIM in the longitudinal direction. In some embodiments, a dam structure or structures surround the TIM in a lateral direction and block or inhibit flow of melted portions of the TIM in the lateral direction.

FIG. 1 is an overhead schematic view of a device structure 100 during a stage of fabrication, in accordance with some embodiments. As shown, the structure includes a thermal interface material (TIM) 200. The TIM 200 has a lateral length W1 extending in a lateral direction, i.e., in the X-direction, from a first end 211 to a second end 212. Further, the TIM 200 has a longitudinal length L1 extending in a longitudinal direction, i.e., in the Y-direction, from a first edge 221 to a second edge 222. In some embodiments, TIM 200 matches the molding-chiplet die size, such that the molding-chiplet die size has a lateral length W1 and longitudinal length L1. In some embodiments, a ratio of the lateral length W1 to the longitudinal length L1 (W1/L1) may be from 0.3 to 3. Generally, the metal TIM 200 coverage is less than or equal to the molding-chiplet die area.

As shown, TIM 200 lies over a substrate 300 having a topside 301 and a periphery 310. As further shown, an adhesive 350 is disposed on the topside 301 of the substrate 300 along the periphery 310.

In FIG. 1, TIM 200 is almost completely surrounded by a dam structure 400. Specifically, dam structure includes a first portion 411 and a second portion 412. Each portion 411 and 412 may be C-shaped, such as a “block C” shape. As shown, each portion 411 and 412 extends from a first end 401 to a second end 402. Further, each portion 411 and 412 includes a first laterally-extending leg 403, a longitudinally-extending base portion 404, and a second laterally-extending leg 405. Thus, each portion 411 and 412 includes a central base portion 404 with a leg 403 and 405 extending from each end of the base portion 404. In the illustrated embodiments, each leg 403 and 405 is substantially perpendicular to the base portion 404. Thus, in the illustrated embodiment, the legs 403 and 405 are parallel to one another. As shown, the legs 403 of each portion 411 and 412 terminate at respective first ends 401 that are aligned with and adjacent to one another. Likewise, the legs 405 of each portion 411 and 412 terminate at respective second ends 402 that are aligned with and adjacent to one another. Other geometrical designs for the portions 411 and 412 are contemplated.

The base portion 404 of the first portion 411 of the dam structure 400 lies adjacent to the first end 211 of TIM 200 continuously from the first edge 221 to the second edge 222. The base portion 404 of the second portion 412 of the dam structure 400 lies adjacent to the second end 212 of TIM 200 continuously from the first edge 221 to the second edge 222.

A first gap 431 in the dam structure 400 is defined between the first end 401 of the first portion 411 and the first end 401 of the second portion 412. A second gap 432 in the dam structure 400 is defined between the second end 402 of the first portion 411 and the second end 402 of the second portion 412.

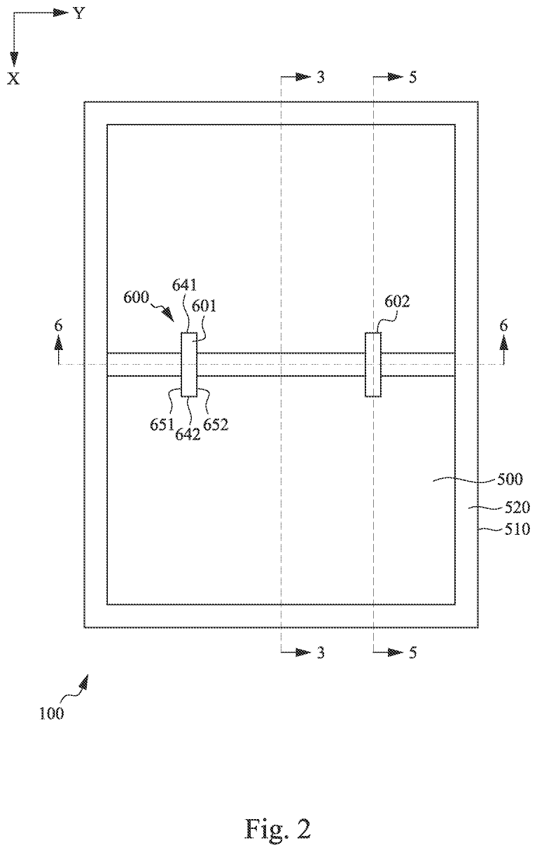

FIG. 2 illustrates a lid 500 covering the substrate 300 of FIG. 1. In FIG. 2, the lid 500 is partially translucent such that features on the underside of the lid 500 are visible. Specifically, the lid 500 includes a periphery 510 with an annular footing 520 that extends vertically, i.e., in a Z-direction illustrated in the following figures, to a bottom edge (not shown). The bottom edge of the footing 520 may be contacted to and adhered to adhesive 350 of the structure 100 of FIG. 1. Further, the lid 500 includes protrusions 600, including a first protrusion 601 and a second protrusion 602. Each protrusion 600 extends vertically, i.e., in a Z-direction illustrated in the following figures, to a bottom edge (not shown). Further, each protrusion 600 extends in the lateral direction, i.e., in the X-direction, from a first end 641 to a second end 642. Also, each protrusion 600 extends in the longitudinal direction, i.e., in the Y-direction, from a first edge 651 to a second edge 652.

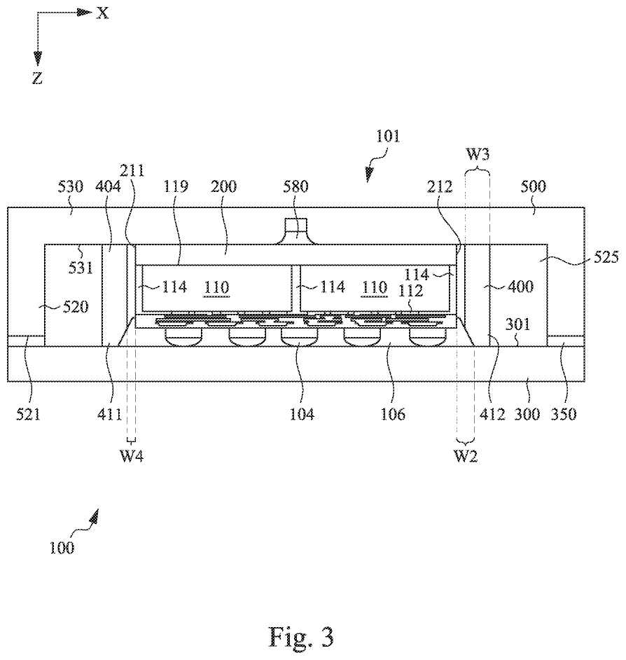

FIG. 3 is a cross-sectional view taken along line 3-3 in FIGS. 1 and 2, in accordance with some embodiments.

As shown, the device structure 100 may be a packaged semiconductor device. For example, the packaged semiconductor device 100 includes an integrated circuit die 110 that has been packaged. In some embodiments, the die 110 may be a system-on-chip (SOC) or include one or more dies, such as one or more systems-on-chips.

The packaged semiconductor device 100 includes an interconnect structure 112 coupled to the integrated circuit die 110, and a molding material 114 disposed around the integrated circuit die 110 and over the interconnect structure 112. The packaged semiconductor device 100 comprises fan-out structures in some embodiments. For example, conductive wiring of the interconnect structure 112 may be spaced apart farther than conductive wiring of the integrated circuit die 110 is spaced. Likewise, the footprint of contact pads of the interconnect structure 112 may be larger than the footprint of contacts (not shown) of the integrated circuit die 110. The packaged semiconductor device 100 comprises an integrated fan-out (InFO) device or a WLP device in some embodiments. The packaged semiconductor device 100 may also comprise other types of packages.

The integrated circuit die 110 may comprise a substrate having electrical circuitry formed within or thereon. The substrate may comprise, for example, doped or undoped bulk silicon or an active layer of a semiconductor-on-insulator (SOI) substrate. The electrical circuitry of the substrate of the integrated circuit die 110 may be any type of circuitry suitable for a particular application. The integrated circuit die 110 may comprise a logic, memory, processor, or other type of device. As other examples, electrical circuitry formed within or on the substrate of the integrated circuit die 110 may include various N-type metal-oxide semiconductor (NMOS) and/or P-type metal-oxide semiconductor (PMOS) devices, such as transistors, capacitors, resistors, diodes, photo-diodes, fuses, and the like, that are interconnected to perform one or more functions. The functions may include memory structures, logic structures, processing structures, sensors, amplifiers, power distribution, input/output circuitry, and/or the like. One of ordinary skill in the art will appreciate that the above examples are provided for illustrative purposes to further explain applications of some illustrative embodiments and are not meant to limit the disclosure in any manner. Other circuitry may be used as appropriate for a given application. The integrated circuit die 110 typically has been fabricated by forming a plurality of the integrated circuit dies 110 on a semiconductor wafer, and singulating the individual integrated circuit dies 110 along scribe lines.

A packaging process for the integrated circuit die 110 in some embodiments comprises providing a carrier (not shown), and attaching the integrated circuit die 110 to the carrier. The carrier may comprise a wafer, tape, or other type of support, substrate, or device that may be used for the packaging process as a platform for packaging one or more integrated circuit dies 110. The carrier is later removed after packaging a plurality of the integrated circuit dies 110 in some embodiments, for example.

In some embodiments, through-vias (not shown in FIG. 3) are also formed over the carrier. The through-vias may be plated on a seed layer formed on the carrier, for example. In some embodiments, through-vias are not included. A plurality of the through-vias may be formed in some embodiments over the carrier by plating, lithography, or other methods, before or after the plurality of the integrated circuit dies 110 is coupled to the carrier. The plurality of through-vias may be formed using an electro-plating process, by depositing a seed layer over the carrier, and forming a patterned mask with a desired pattern for the through-vias over the seed layer. The through-vias are plated onto the carrier through the patterned mask, and the patterned mask is then removed. The exposed portions of the seed layer are also removed. The through-vias may comprise copper, a copper alloy, or other metals or conductive materials. Dozens or hundreds of through-vias may be included in a package for each of the integrated circuit dies 110 or groups of integrated circuit dies 110 that are packaged together, for example. The plurality of through-vias provides electric connections in a vertical direction for the packaged semiconductor devices 100 in some embodiments. Each of the plurality of through-vias may be positioned so that they will be coupled to a conductive portion of the interconnect structure 112 that will later be formed, for example.

A plurality of the integrated circuit dies 110 is coupled to the carrier between some of the plurality of through-vias in some embodiments. The plurality of integrated circuit dies 110 is coupled to the carrier using a die attach film (DAF) (not shown) disposed on a bottom surface of the integrated circuit dies 110. The plurality of integrated circuit dies 110 may be placed on the carrier using a pick-and-place machine or manually, for example. In some embodiments, a plurality of the integrated circuit dies 110 is coupled to the carrier and is packaged simultaneously. The integrated circuit die 110 or two or more integrated circuit dies 110 are later singulated along scribe lines (i.e., of the package or interconnect structure 112) to form a plurality of packaged semiconductor devices 100.

The molding material 114 is then formed over the carrier, over the integrated circuit die 110 and the through-vias, in embodiments wherein the through-vias are included. The molding material 114 may comprise a molding compound comprised of an insulating material, such as an epoxy, a filler material, a stress release agent (SRA), an adhesion promoter, other materials, or combinations thereof, as examples. The molding material 114 may comprise a liquid or gel when applied so that it flows between a plurality of integrated circuit dies 110 being simultaneously packaged and around the through-vias, in some embodiments. The molding material 114 is then cured or allowed to dry so that it forms into a solid. A molding compound clamp may be applied during a curing process and a plasma treatment process of the molding material 114 in some embodiments. In some embodiments, as deposited, the molding material 114 extends over top surfaces of the plurality of integrated circuit dies 110 and the through-vias, and after the molding material 114 is applied, a top portion of the molding material 114 is removed using a planarization process, such as a chemical mechanical polish (CMP) process, a grinding process, an etch process, or combinations thereof, as examples. Other methods may also be used to planarize the molding material 114. A top portion of the integrated circuit dies 110 and/or through-vias may also be removed during the planarization process for the molding material 114. In some embodiments, an amount of the molding material 114 applied may be controlled so that top surfaces of the integrated circuit die 110 and through-vias are exposed. Other methods may also be used to form the molding material 114.

The interconnect structure 112 may then be formed over the planarized molding material 114, the integrated circuit dies 110, and the through-vias. The interconnect structure 112 comprises an RDL or PPI in some embodiments. The interconnect structure 112 may include one, two, or several conductive line layers and via layers. Some of the conductive lines of the interconnect structure 112 are coupled to contact pads (not shown) of the integrated circuit die 110. The conductive features or wiring of the interconnect structure may comprise copper, a copper alloy, or other metals formed by plating processes, lithography processes, and/or other methods formed within one or more insulating material layers, in some embodiments.

The carrier wafer is then removed. In some embodiments, a plurality of the packaged semiconductor devices 100 is then singulated to form the packaged semiconductor device 100 shown in FIG. 3 (for example, in an inverted view, with the interconnect structure 112 at the bottom). The packaged semiconductor devices 100 may be singulated using a saw or laser (not shown), which may include a blade comprising diamond or other materials in some embodiments, for example. One or more carriers may be used to package a semiconductor device.

In some embodiments, the interconnect structure 112 comprises a first interconnect structure formed on a first side of the integrated circuit die 110, and a second interconnect structure (not shown) is formed in addition to the first interconnect structure 112 on a second side of the integrated circuit die 110, the second side being opposite the first side, before singulating a plurality of the packaged semiconductor devices 100. For example, the previously described carrier may comprise a first carrier, and after the formation of the first interconnect structure 112, a second carrier may be attached to the first interconnect structure. The first carrier is removed, and the second interconnect structure is formed over the second side of the integrated circuit die 110, the through-vias, and the molding material 114. The second carrier is then removed, and the packaged semiconductor devices 100 are then singulated. The first interconnect structure 112 and the second interconnect structure may provide electrical connections in a horizontal direction for a plurality of packaged semiconductor devices 100 in some embodiments, for example. The second interconnect structure may comprise back-side routing, and the first interconnect structure 112 comprises front-side routing, or vice versa, e.g., relative to the integrated circuit die 110, for the packaged semiconductor devices 100 in some embodiments.

The methods of packaging semiconductor devices using one or more carriers described herein is merely an example: the integrated circuit dies 110 may be packaged using different methods or orders of methods of a packaging process.

In some embodiments, the packaged semiconductor device 100 is coupled to a substrate or printed circuit board (PCB) 300 by a plurality of connectors 104, as shown in FIG. 3. The connectors 104 may comprise a eutectic material such as solder, and the connectors 104 may be arranged in a ball grid array (BGA) that is fully or partially populated, for example. The use of the word “solder” herein includes both lead-based and lead-free solders, such as Pb—Sn compositions for lead-based solder; lead-free solders including InSb; tin, silver, and copper (“SAC”) compositions; and other eutectic materials that have a common melting point and form conductive solder connections in electrical applications. For lead-free solder, SAC solders of varying compositions may be used, such as SAC 105 (Sn 98.5%, Ag 1.0%, Cu 0.5%), SAC 305, and SAC 405, as examples. Lead-free conductive materials such as solder balls may be formed from SnCu compounds as well, without the use of silver (Ag). Lead-free solder connectors 104 may also include tin and silver, Sn—Ag, without the use of copper. In some embodiments, the connectors 104 may comprise solder bumps or solder balls, as examples. The connectors 104 comprise conductive balls having a shape of a partial sphere in some embodiments. The connectors 104 may also comprise other shapes, such as non-spherical conductive connectors, for example. In some embodiments, the connectors 104 may comprise metal pillars (such as a copper pillars) formed by a sputtering, printing, electro plating, electroless plating, chemical vapor deposition (CVD), or the like. The metal pillars may be solder free and have substantially vertical sidewalls. In some embodiments, a metal cap layer (not shown) is formed on the top of the metal pillar connectors 104. The metal cap layer may include nickel, tin, tin-lead, gold, silver, palladium, indium, nickel-palladium-gold, nickel-gold, the like, or a combination thereof and may be formed by a plating process. The connectors 104 may also be used to couple the packaged semiconductor device 100 to other types of devices, such as to another packaged semiconductor device, an unpackaged semiconductor device, or directly in an end application, as examples.

In some embodiments, the interconnect structure 112 of the packaged semiconductor device 100 is coupled to the substrate or PCB 300 using the plurality of connectors 104, as illustrated in FIG. 3. The connectors 104 are coupled between contact pads (not shown) on the substrate or PCB 300 and contact pads of the interconnect structure 112. The connectors 104 are coupled to the contact pads of the substrate or PCB 300 by aligning the connectors 104 with the contact pads of the substrate or PCB 300, and heating the connectors 104 to the melting point of the eutectic material of the connectors 104, which reflows the material of the connectors 104. The material of the connectors 104 is allowed to cool, leaving the connectors 104 electrically and mechanically coupled to the contact pads of the substrate or PCB 300, and coupling the packaged semiconductor device 100 to the substrate or PCB 300.

An underfill material 106 may be applied between the connectors 104 and between the interconnect structure 112 and the substrate or PCB 300. The underfill material 106 may comprise a similar material as described for the molding material 114, for example. The underfill material 106 may be dispensed along one or more sides of the interconnect structure 112 along edge connectors 104, for example, and the underfill material 106 flows beneath the packaged semiconductor device 100 to the other side(s). The underfill material 106 is then cured or allowed to cure. In some embodiments, the underfill material 106 is not included.

In FIG. 3, the underfill 106 may extend laterally past the ends 211, 212 in the X-direction, by a lateral width W2. In some embodiments, lateral width W2 is from zero to 10 mm.

As shown in FIG. 3, a thermal interface material (TIM) 200 is applied to a top surface 119 of the integrated circuit die 110 and a top surface of the molding material 114 in some embodiments. TIM 200 may comprise a metal such as a solder material. In some embodiments, TIM 200 is indium (In) or silver (Ag), or a combination of In and Ag. For example, TIM 200 may be 99.99% In, 90% In and 10% Ag, or may include greater than or equal to 80% Ag.

The TIM 200 may comprise a thickness of about 20 μm to about 150 μm, as examples. The TIM 200 may also comprise other materials and dimensions. The TIM 200 may be applied by dispensing the TIM 200 onto the top surface of the integrated circuit die 110 and molding material 114. The dispensing process may be conducted using automatic dispenser equipment which may control the TIM 200 dispensing volume and patterns, such as serpentine, spiral, or other patterns, in order to achieve full coverage and a desired TIM 200 bond line thickness. The TIM 200 may also be applied using other methods.

As further shown in FIG. 3, the lid 500 or cooling device is coupled to the TIM 200 using an automated pick-and-place machine or equipment, or other methods. The lid 500 is coupled to the integrated circuit die 110 and the molding material 114 by the TIM 200 in some embodiments, for example. The lid 500 advantageously provides cooling and thermal dissipation for heat from the integrated circuit die 110. The lid 500 is adapted to dissipate heat from the integrated circuit die 110, the interconnect structure 112, and/or the molding material 114 in some embodiments, for example.

As shown, the lid 500 has a central portion 530 and includes a periphery 510 with an annular footing 520 that extends vertically downward, i.e., in the Z-direction, from the central portion 530 to a bottom edge 521. The bottom edge 521 of the footing 520 is contacted to and adhered to adhesive 350. The footing 520 defines an interior volume 525 enclosed by the lid 500. As shown, the die 110 and TIM 200 are received in the interior volume 525.

As further shown in FIG. 3, the central portion 530 has an underside 539. The underside 539 may be substantially planar. As shown, the underside 539 contacts the TIM 200.

In some embodiments, the underside 539 of the central portion 530 of the lid 500 is formed with a trench 580. Further, an insert 590 is located in, and only partially fills the trench 580. In some embodiments, the insert 590 is a polymer material. For example, the insert 590 may be a polymer TIM.

In FIG. 3, the structure 100 further includes dam structure 400. As shown, the dam structure 400 may include two separate portions-first portion 411 and second portion 412. Each dam portion 411, 412 contacts the underside 539 of the lid 500 and the topside 301 of the substrate 300. Each dam portion 411, 412 may contact the underfill 106. As shown, each dam portion 411, 412 has a lateral width W3 in the X-direction. Further, each dam portion 411, 412 is located at a lateral distance W4 in the X-direction from an end 211, 212 of TIM 200.

In some embodiments, a ratio of the lateral distance W4 to the lateral underfill width W2 (W4/W2) is less than or equal to 1.

In some embodiments, a ratio of the lateral dam width W3 to the lateral distance W4 (W3/W4) is less than or equal to 1.

The cross-sectional view of FIG. 3 passes through the base portion 404 of each dam portion 411, 412. As shown, the base portion 404 of the first portion 411 of the dam structure 400 lies adjacent to the first end 211 of TIM 200, and the base portion 404 of the second portion 412 of the dam structure 400 lies adjacent to the second end 212 of TIM 200.

In some embodiments, each dam portion 411, 412 is formed by a polymer TIM.

The connectors 104, underfill material 106, interconnect structure 112, integrated circuit die 110 may be collectively referred to as a workpiece 101 that is located over the substrate 300.

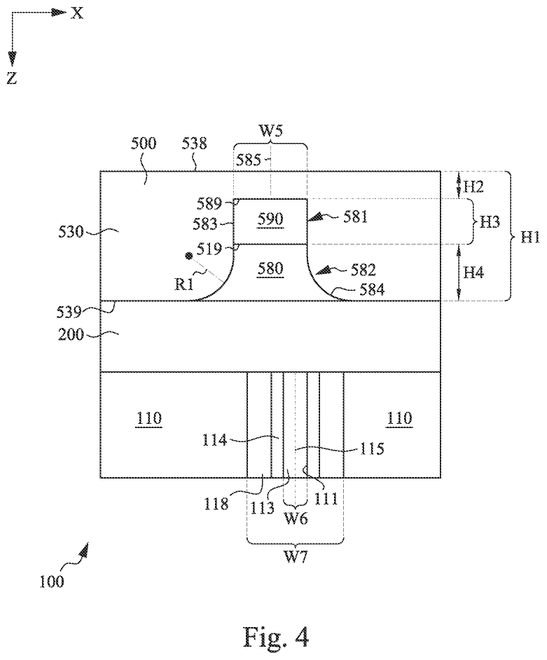

FIG. 4 illustrates a focused cross-sectional view of the trench 580 formed in the underside 539 of the lid 500. As shown, the lid 500 has a top surface 538. Further, the central portion 530 of the lid 500 has a vertical thickness H1, in the Z-direction, extending from top surface 538 to underside 539.

As shown, the trench 580 includes an upper portion 581 and a lower portion 582. The upper portion 581 extends vertically downward, in the Z-direction, from an upper trench surface 589 along substantially planar sidewalls 583. The lower portion 582 includes arcuate sidewalls 584. For example, each arcuate sidewall 584 may be formed with a radius R1. In some embodiments, radius R1 may be from 0.025 to 0.6 mm.

Further, the sidewalls 583 in the upper portion 581 of the trench 580 may be laterally distanced from one another by a distance W5 in the X-direction. A vertical centerline 585 is defined as being equidistant between the sidewalls 583.

The upper trench surface 589 may be located at a vertical distance H2 in the Z-direction from the top surface 538. In other words, the lid 500 has a vertical thickness H2 over the trench 580. The vertical thickness H2 is greater than zero and is less than that vertical thickness H1.

As shown in FIG. 4, the insert 590 may be located in the upper portion 581 of trench 580. More specifically, the insert 590 may abut the upper trench surface 589. The insert 590 may have a lowest surface 591. Further, the insert 590 may have a vertical thickness H3, in the Z-direction, extending from the upper trench surface 589 to the lowest surface 591. Also, the lowest surface 591 of the insert 590 may be located at a vertical height H4, in the Z-direction, over the underside 539.

The trench 580 has a total depth equal to the sum of H3 and H4, i.e., the vertical distance from the upper trench surface 589 to the underside 539. In embodiments, H3+H4 is less than H1.

FIG. 4 illustrates that each die 110 may include a scribe line and/or embedded seal ring 118 and may extend laterally in the X-direction to a chip edge 111. Further, the chip edges 111 may be separated from one another by a gap 113 having a lateral distance W6 in the X-direction, i.e., a die-to-die gap 113. The die-to-die gap 113 is defined with a vertical centerline 115 that is equidistance to each of the chip edges 111. The molding material 114 fill the die-to-die gap 113, such that the inter-die portion of the molding material 114 has a thickness equal to the lateral distance W6.

A width W7 may include the inter-die portion of the molding material 114 and the scribe line and/or embedded seal ring 118 of each die 110.

In the illustrated embodiment, trench 580 may be located directly over the die-to-die gap 113. In some embodiments the lateral distance, in the X-direction, between the centerline 585 of the trench 580 and the centerline 115 of the die-to-die gap 113 is from zero to 0.5 mm.

In some embodiments, the lateral distance W6 of the die-to-die gap 113 is less than the trench width W5. In some embodiments, the trench width W5 is less than or equal to the width W7.

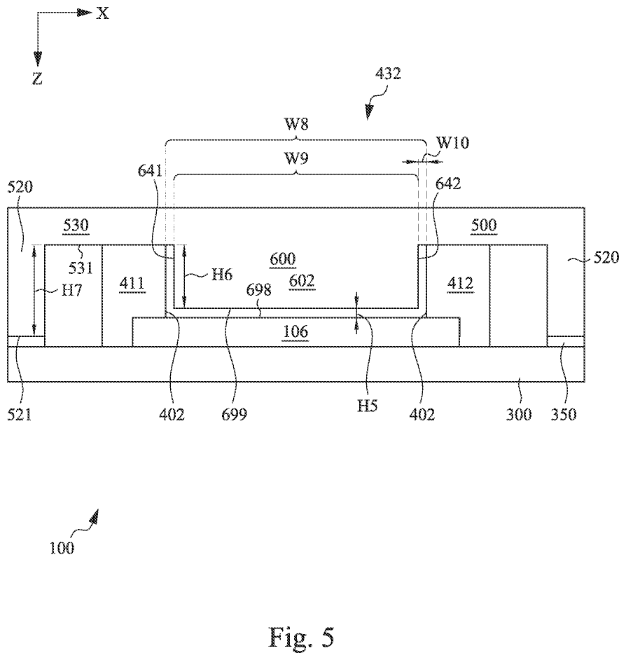

FIG. 5 is a cross-sectional view taken along line 5-5 in FIGS. 1 and 2, in accordance with some embodiments. As shown, the second gap 432 is defined between the second end 402 of the first portion 411 of the dam structure 400 and the second end 402 of the second portion 412 of the dam structure 400. The gap 432 has a lateral width W8 in the X-direction.

Further, the protrusion 600, specifically protrusion 602, extends vertically downward in the Z-direction from the underside 531 of the lid 500 into the gap 432. The protrusion 600 terminates at a lowest surface 699. As shown, the protrusion 600 has a lateral width W9 in the X-direction from first end 641 to second end 642.

Cross-referencing FIGS. 1 and 5, in some embodiments, protrusion width W9 is greater than zero and less than or equal to lateral length W1.

In FIG. 5, each end 641, 642 of protrusion 600 is laterally distanced in the X-direction from the adjacent dam structure 411 or 412 by distance W10. In some embodiments, distance W10 is less than 20 mm.

The cross-sectional view of FIG. 5 does not pass through the workpiece including the die 110, interconnect structure 112, or TIM 200. The underfill material 106 does extend beyond the other workpiece components in the Y-direction such that the cross-sectional view of FIG. 5 illustrates the underfill material 106. As shown, the underfill material 106 has an uppermost surface 698.

A vertical distance H5 in the Z-direction is defined between the lowest surface 699 of the protrusion 600 and the uppermost surface 698 of the underfill material 106.

Further, the protrusion 600 has a vertical length H6 in the Z-direction from the underside 531 to the lowest surface 699.

As shown, the footing 520 extends vertically downward in the Z-direction for a vertical distance H7 from the underside 531 to bottom edge 521. The bottom edge 521 of the footing 520 is contacted to and adhered to adhesive 350. Cross-referencing FIGS. 4 and 5, it may be seen that a ratio of the lid thickness H1 to footing length H7 (H1/H7) is from 0 to 2.

In some embodiments, the vertical protrusion length H6 is greater than zero and less than the vertical footing length H7.

In some embodiments, vertical distance H5 is greater than zero and less than the vertical footing length H7.

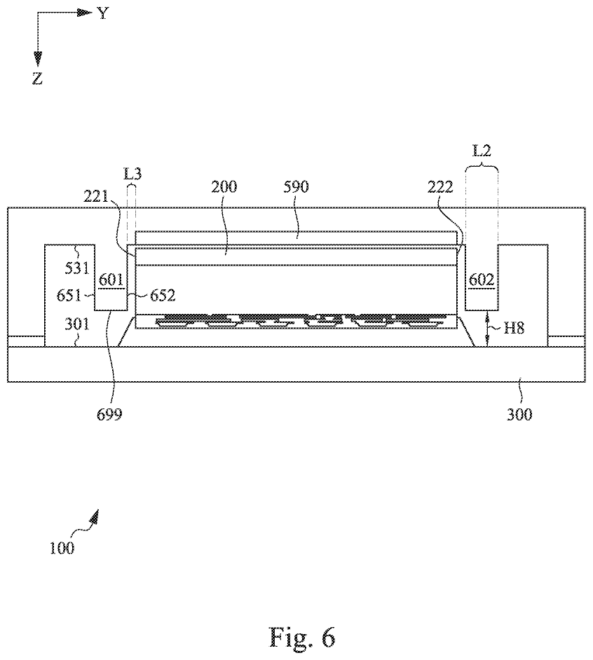

FIG. 6 is a cross-sectional view taken along line 6-6 in FIGS. 1 and 2, in accordance with some embodiments.

As shown, each protrusion 601, 602 extends downward from the underside 531 to lowest surface 699. Lowest surface 699 is at a vertical distance H8 in the Z-direction from the topside 301 of the substrate 300.

In some embodiments, vertical distance H8 is greater than zero and less than the vertical footing length H7.

Each protrusion 601, 602 has a longitudinal length L2 in the Y-direction from first or outer edge 651 to second or inner edge 652. Longitudinal length L2 is greater than zero. Further, the inner edge 652 of each protrusion 601, 602 is distanced from a respective edge 221, 222 of TIM 200 by a longitudinal distance L3 in the Y-direction.

In some embodiments, the ratio of longitudinal distance L3 to lateral underfill width W2 (L3/W2) is less than or equal to 1.

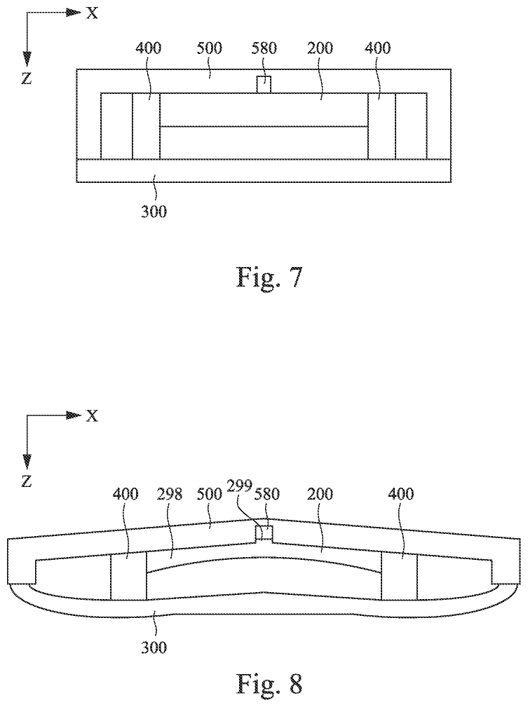

FIGS. 1-6 are schematics illustrating the assembly of components. FIGS. 7-10 illustrate the deformation and movement of components during an anneal process.

FIG. 7 is a simplified schematic similar to FIG. 3, illustrating the structure of the device before a thermal anneal process. As shown, the lid 500 and trench 580 are located over TIM 200. No polymer insert is illustrated as partially filling trench 580. However, it is contemplated that the polymer insert may be located in trench 580. As further shown, TIM 200 and the remaining portion of the workpiece is located between the portions of the dam structure 400.

FIG. 8 is a cross-sectional schematic of the structure of FIG. 7 after a thermal anneal process. During the thermal anneal process, the substrate 300 and lid 500 may undergo warpage as shown. The trench 580 may reduce rigidity of the lid 500 to reduce stress. Also, the polymer dam structure 400 may control the lid-to-substrate warpage.

Further, during the thermal anneal process, all or of portions of TIM 200 may melt. As shown, a vertically-extending portion 299 of TIM 200 may flow into the trench 580 while a base portion 298 of the TIM 200 remains outside the trench 580. At the same time, the dam structure 400 prevents flow of melted portions of TIM 200 laterally in the X-direction.

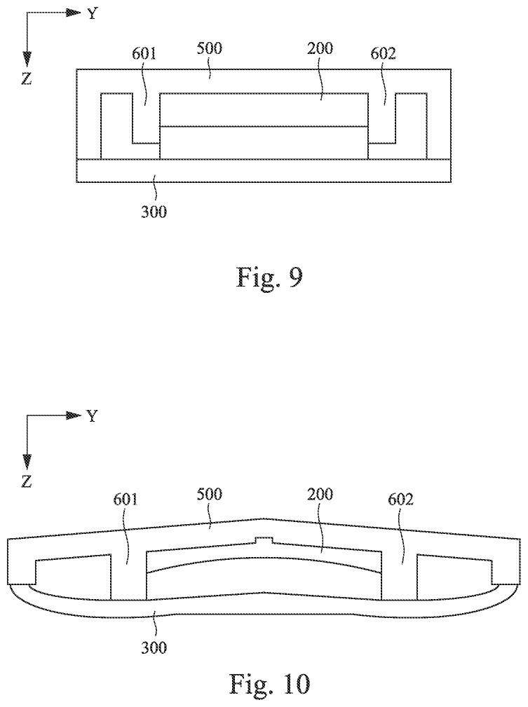

FIG. 9 is a simplified schematic similar to FIG. 6, illustrating the structure of the device before a thermal anneal process. As shown, the lid 500 is located over TIM 200. As further shown, TIM 200 and the remaining portion of the workpiece is located between the protrusions 601 and 602. Further, the protrusions 601 and 602 are distanced from the substrate 300 so that a vacuum may be applied to draw air bubbles out of TIM 200 during the anneal process.

FIG. 10 is a cross-sectional schematic of the structure of FIG. 9 after a thermal anneal process. During the thermal anneal process, the substrate 300 and lid 500 may undergo warpage as shown. Further, during the thermal anneal process, all or of portions of TIM 200 may melt. Protrusions 601 and 602 prevent flow of melted portions of TIM 200 longitudinally in the Y-direction.

As described herein, embodiments provide for lids such as cooling structures that mitigate stress on underlying structures during thermal anneal processes. Further, such lids may include locations, such as trenches, that provide open space to receive flow of melted material, such as in a vertical direction. As a result, flow of melted material may be redirected away from non-desired directions. Also, such lids may be provided with downward-extending protrusions that limit the flow of melted material in longitudinal directions. Also, embodiments herein provide non-metal, such as polymeric TIM, dam structures that limit the flow of melted material in lateral directions.

In one embodiment, a device includes a workpiece; a thermal interface material (TIM) disposed over the workpiece; and a lid disposed over the workpiece, wherein the lid has an underside formed with a trench, and wherein a vertically extending portion of the TIM extends into the trench and a base portion of the TIM is located outside of the trench.

In some embodiments of the device, the TIM extends longitudinally from a first edge to a second edge; the lid includes a first protrusion extending downward the underside of the lid, wherein the first protrusion is longitudinally adjacent to the first edge; and the lid includes a second protrusion extending downward from the underside of the lid, wherein the second protrusion is longitudinally adjacent to the second edge.

In some embodiments of the device, the TIM extends laterally from a first end to a second end; and the device further includes a first portion of a dam structure laterally adjacent to the first end of the TIM and a second portion of a dam structure laterally adjacent to the second end of the TIM.

In some embodiments of the device, a first gap is located between the first portion and the second portion of the dam structure adjacent to the first edge of the TIM; a second gap is located between the first portion and the second portion of the dam structure adjacent to the second edge of the TIM; the first protrusion extends downward into the first gap; and the second protrusion extends downward into the second gap.

In some embodiments of the device, the TIM is metal and the dam structure is a polymer.

In some embodiments, the workpiece is an integrated circuit die.

In another embodiment, a device includes a system-on-chip (SOC); a substrate, wherein the SOC is mounted to the substrate; a lid disposed over the SOC; a thermal interface material (TIM) disposed between the SOC and the lid, wherein the TIM extends laterally from a first end to a second end; and a dam structure laterally adjacent to the first end of the TIM and to the second end of the TIM.

In some embodiments of the device, the lid has an underside; the substrate has a topside; and the dam structure extends vertically from the topside of the substrate to the underside of the lid.

In some embodiments of the device, the TIM is metal.

In some embodiments of the device, the dam structure is a polymer.

In some embodiments of the device, the TIM extends longitudinally from a first edge to a second edge; the dam structure includes a first portion laterally adjacent to the first end of the TIM; the dam structure includes a second portion laterally adjacent to the second end of the TIM; a first gap is located between the first portion and the second portion of the dam structure adjacent to the first edge of the TIM; a second gap is located between the first portion and the second portion of the dam structure adjacent to the second edge of the TIM; the lid includes a first protrusion extending downward into the first gap from an underside of the lid; and the lid includes a second protrusion extending downward into the second gap from the underside of the lid.

In some embodiments of the device, the lid has an underside; a trench is formed in the underside of the lid over the workpiece; and a vertically extending portion of the TIM extends into the trench.

In some embodiments of the device, a polymer insert material is located in the trench over the vertically extending portion.

In some embodiments of the device, the TIM directly contacts the SOC and an underside of the lid.

In another embodiment, a method includes locating a workpiece over a package carrier; disposing a thermal interface material (TIM) over the workpiece; positioning a lid over the workpiece, wherein the lid has an underside formed with a trench, and wherein the lid has an annular footing; adhering the footing to the package carrier; and performing a thermal anneal process, wherein during the thermal anneal process a portion of the TIM melts and flows into the trench.

In some embodiments of the method, after disposing the TIM over the workpiece, the TIM extends longitudinally from a first edge to a second edge; the lid includes a first protrusion and a second protrusion extending downward the underside of the lid; after adhering the footing to the package carrier, the first protrusion is longitudinally adjacent to the first edge and the second protrusion is longitudinally adjacent to the second edge; and during the thermal anneal process, the first protrusion and the second protrusion block longitudinal flow of melted portions of the TIM.

In some embodiments, the method further includes applying a vacuum to draw bubbles out of the TIM during the thermal anneal process.

In some embodiments of the method, after disposing the TIM over the workpiece, the TIM extends laterally from a first end to a second end; the method further includes forming a dam structure over the package carrier; after disposing the TIM over the workpiece, the dam structure is laterally adjacent to the first end of the TIM and to the second end of the TIM; and during the thermal anneal process, the dam structure blocks lateral flow of melted portions of the TIM.

In some embodiments, the method further includes, before positioning the lid over the workpiece, partially filling the trench with a polymer insert.

In some embodiments of the method, the workpiece includes a first system-on-chip (SOC) and a second system-on-chip (SOC) separated by a gap; and positioning the lid over the workpiece includes positioning the trench directly over the gap.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a workpiece;
a thermal interface material (TIM) disposed over the workpiece; and
a lid disposed over the workpiece, wherein the lid has an underside formed with a trench, and wherein a vertically extending portion of the TIM extends into the trench and a base portion of the TIM is located outside of the trench.

2. The device of claim 1, wherein:
the TIM extends longitudinally from a first edge to a second edge;
the lid includes a first protrusion extending downward the underside of the lid, wherein the first protrusion is longitudinally adjacent to the first edge; and
the lid includes a second protrusion extending downward from the underside of the lid, wherein the second protrusion is longitudinally adjacent to the second edge.

3. The device of claim 2, wherein:
the TIM extends laterally from a first end to a second end; and
the device further comprises a first portion of a dam structure laterally adjacent to the first end of the TIM and a second portion of a dam structure laterally adjacent to the second end of the TIM.

4. The device of claim 3, wherein:
a first gap is located between the first portion and the second portion of the dam structure adjacent to the first edge of the TIM;
a second gap is located between the first portion and the second portion of the dam structure adjacent to the second edge of the TIM;
the first protrusion extends downward into the first gap; and
the second protrusion extends downward into the second gap.

5. The device of claim 3, wherein the TIM is metal and the dam structure is a polymer.

6. The device of claim 1, wherein the workpiece is an integrated circuit die.

7. A device, comprising:
a system-on-chip (SOC);
a substrate, wherein the SOC is mounted to the substrate;
a lid disposed over the SOC;
a thermal interface material (TIM) disposed between the SOC and the lid, wherein the TIM extends laterally from a first end to a second end; and
a dam structure laterally adjacent to the first end of the TIM and to the second end of the TIM.

8. The device of claim 7, wherein:
the lid has an underside;
the substrate has a topside; and
the dam structure extends vertically from the topside of the substrate to the underside of the lid.

9. The device of claim 7, wherein the TIM is metal.

10. The device of claim 7, wherein the dam structure is a polymer.

11. The device of claim 7, wherein:
the TIM extends longitudinally from a first edge to a second edge;
the dam structure includes a first portion laterally adjacent to the first end of the TIM;
the dam structure includes a second portion laterally adjacent to the second end of the TIM;
a first gap is located between the first portion and the second portion of the dam structure adjacent to the first edge of the TIM;
a second gap is located between the first portion and the second portion of the dam structure adjacent to the second edge of the TIM;
the lid includes a first protrusion extending downward into the first gap from an underside of the lid; and
the lid includes a second protrusion extending downward into the second gap from the underside of the lid.

12. The device of claim 7, wherein:
the lid has an underside;
a trench is formed in the underside of the lid over the SOC; and
a vertically extending portion of the TIM extends into the trench.

13. The device of claim 12, wherein a polymer insert material is located in the trench over the vertically extending portion.

14. The device of claim 7, wherein the TIM directly contacts the SOC and an underside of the lid.

15. A method comprising:
locating a workpiece over a package carrier;
disposing a thermal interface material (TIM) over the workpiece;
positioning a lid over the workpiece, wherein the lid has an underside formed with a trench, and wherein the lid has an annular footing;
adhering the footing to the package carrier; and
performing a thermal anneal process, wherein during the thermal anneal process a portion of the TIM melts and flows into the trench.

16. The method of claim 15, wherein:
after disposing the TIM over the workpiece, the TIM extends longitudinally from a first edge to a second edge;
the lid includes a first protrusion and a second protrusion extending downward the underside of the lid;
after adhering the footing to the package carrier, the first protrusion is longitudinally adjacent to the first edge and the second protrusion is longitudinally adjacent to the second edge; and
during the thermal anneal process, the first protrusion and the second protrusion block longitudinal flow of melted portions of the TIM.

17. The method of claim 16, further comprising:
applying a vacuum to draw bubbles out of the TIM during the thermal anneal process.

18. The method of claim 15, wherein:
after disposing the TIM over the workpiece, the TIM extends laterally from a first end to a second end;
the method further comprises forming a dam structure over the package carrier;
after disposing the TIM over the workpiece, the dam structure is laterally adjacent to the first end of the TIM and to the second end of the TIM; and
during the thermal anneal process, the dam structure blocks lateral flow of melted portions of the TIM.

19. The method of claim 15, further comprising, before positioning the lid over the workpiece, partially filling the trench with a polymer insert.

20. The method of claim 15, wherein:
the workpiece comprises a first system-on-chip (SOC) and a second system-on-chip (SOC) separated by a gap; and
positioning the lid over the workpiece comprises positioning the trench directly over the gap.
